(19) United States
(12) Patent Application Publication
(10) Pub. No.: US 2009/0058493 A1
(43) Pub. Date: Mar. 5, 2009

(54) Signal Level Converter

(76) Inventors: Matthias Arnold, Freising (DE); Johannes Gerber, Unterschleissheim (DE); Bernhard Wolfgang Ruck, Freising (DE)

Correspondence Address: TEXAS INSTRUMENTS INCORPORATED, P O BOX 655474, M/S 3999, DALLAS, TX, 75265, US

(21) Appl. No.: 12/197,506

(22) Filed: Aug. 25, 2008

Related U.S. Application Data
(60) Provisional application No. 61/016,895, filed on Dec. 27, 2007.

(30) Foreign Application Priority Data
Aug. 31, 2007 (DE) 10 2007 041 558.5

(51) Int. Cl. H03L 5/00

(52) U.S. Cl. 327/333

(57) ABSTRACT

An electronic device with a supply voltage level converter converts a signal from a first low supply voltage level to a second high supply voltage level includes; a first pair of cross coupled MOS transistors compliant with the second supply voltage level, each having a source coupled to the second supply voltage level and providing complementary output signals at respective drains; driven by a second pair of common gate MOS transistors compliant with the second supply voltage; driven by a third pair of common gate MOS transistors compliant with the first voltage level; and driven by first and second inverters coupled in a chain and supplied by the first supply voltage level, each having an output connected to the source of a transistor in a third pair.

### CLAIM OF PRIORITY

This application claims priority under 35 U.S.C. 119(a) to German Patent Application No. 10 2007 041 558.5 filed Aug. 31, 2007 and 35 U.S.C. 119(e)(1) to U.S. Provisional Application No. 61/016,895 filed Dec. 27, 2007.

### TECHNICAL FIELD OF THE INVENTION

The technical field of this invention is electronic devices including a supply voltage converter for converting a signal from a first low supply voltage level to a second high supply voltage level.

### BACKGROUND OF THE INVENTION

In electronic devices which use two different supply levels, signal levels propagating from one supply voltage domain to another have to be adjusted in accordance with the domain. Typically, there might be a supply voltage domain of e.g. 1.8 V for the core of the electronic device and another domain of 3.3 V for the peripheral devices in the same electronic device. Both voltage domains may be incorporated in the same integrated electronic device.

It is evident that logic high and low levels must be adapted when passing the signals from one domain to another. This operation is normally done with level converters or level shifters. There is a problem with these lever converters or shifters. A 1.8 V supply voltage domain supplies components such as transistors which can only withstand voltages up to only little more than 1.8 V. On the other hand, transistors from the high voltage domain or the low voltage domain may require biasing, threshold or reference voltages that often exceed the limited voltage range in the other voltage domain. Therefore, prior art level shifters often require sophisticated mechanisms in order to generate appropriate reference voltages and signal voltage levels that can be handled from either low voltage compliant or high voltage compliant devices. Using high voltage compliant components require more chip area then low voltage components. Furthermore, decreasing the threshold voltage level in a high voltage technology also requires increased chip area.

### SUMMARY OF THE INVENTION

It is an object of the present invention to provide an electronic device including a supply voltage level converter that requires little chip area and is capable of converting signal levels even from very low supply voltage levels to a high supply voltage level.

Accordingly, the present invention is an electronic device with a supply voltage level converter for converting a signal from a first low supply voltage level to a second high supply voltage level. The supply voltage level converter includes a first pair of cross coupled MOS transistors compliant with the second supply voltage level. Each of this first pair of MOS transistors has a source coupled to the second supply voltage level. A drain of each transistor is an output node providing a complementary output signal according to the second supply voltage level. A second pair of MOS transistors is also compliant with the second supply voltage level. Both of the second pair of MOS transistors receives a constant voltage level at their gates. Each of the second pair of MOS transistors has a drain coupled to a drain of one of the MOS transistors of the first pair. First and second inverters are coupled in a chain and supplied with the first supply voltage level. Each of the two inverters is coupled by an output to a source of a MOS transistor in a third pair of MOS transistors compliant with the first voltage level. Each transistor in the third pair is connected in a common gate configuration so that the gate of each transistor receives a constant voltage level. A drain of each MOS transistor in the third pair MOS transistors is coupled to a source of a transistor in the second pair of MOS transistors. The outputs of the two low voltage supplied inverters are fed via the two low voltage compliant MOS transistors in the third pair of MOS transistors. Thus each inverter has an output connected to a source of a low voltage compliant MOS transistor. The third pair of low voltage compliant transistors is connected to the high voltage compliant second pair of transistors, which in turn are connected to the high voltage compliant cross coupled first pair of MOS transistors. Complementary output signals are then generated at the two points where the gate of one transistor in the cross coupled first pair of transistors is connected to the drain of the other transistor in the cross coupled pair. The supply voltage level converter of the present invention therefore employs both low voltage and high voltage compliant devices. The low voltage supply side tolerates low input voltage levels because low voltage devices (MOS transistors) with a lower threshold voltage are used. Overvoltage stress of the (low voltage compliant) third pair of MOS transistors is avoided by connecting the drains of the third pair of transistors to the sources of the second pair of MOS transistors, which are high voltage compliant. Furthermore, since the third pair of MOS transistors operates in a common gate configuration, their drain source voltages do not exceed their predetermined limits. The input capacitance in a common gate configuration is smaller than in a common source configuration. The smaller input capacitance has positive impact on switching speed of the circuit. Using common gate coupled transistors allows the V_{SS} level (ground level for both domains) to be transferred without loss from the inverter output to the sources of the second pair of transistors. By using low voltage compliant devices, which have a lower threshold voltage than high voltage compliant devices, at the input of the supply voltage level converter of the present invention, the tolerable minimum positive supply voltage is very low (about 1.2 V). Even at these very low voltages the device of the present invention is capable of converting signal levels to a high supply voltage level. Also, because the third pair of transistors are low voltage compliant, they can have a thinner gate oxide layer than that required for high voltage compliant devices. This means that the width to length ratio W/L for the third pair of transistors required to achieve a particular current can be smaller than W/L for high voltage compliant devices. This advantageously provides a faster device of reduced chip area. No special bias circuits are required in the device of the present invention.

The gate voltage of the second pair of MOS transistors is preferably the second supply voltage. The gate voltage of the third pair of MOS transistors is preferably the first supply voltage. Using the supply voltage levels in each domain instead of additional bias voltages is advantageous because no additional biasing circuitry is required.

### BRIEF DESCRIPTION OF THE DRAWINGS

These and other aspects of this invention are illustrated in the drawings, in which:

FIG. 1 is a general block diagram of a circuit having two voltage domains;

FIG. 2 is a simplified circuit diagram of a supply voltage level converter according to the prior art; and

FIG. 3 is a simplified circuit diagram of an electronic device with a supply voltage level converter according to this invention.

### DETAILED DESCRIPTION OF PREFERRED EMBODIMENTS

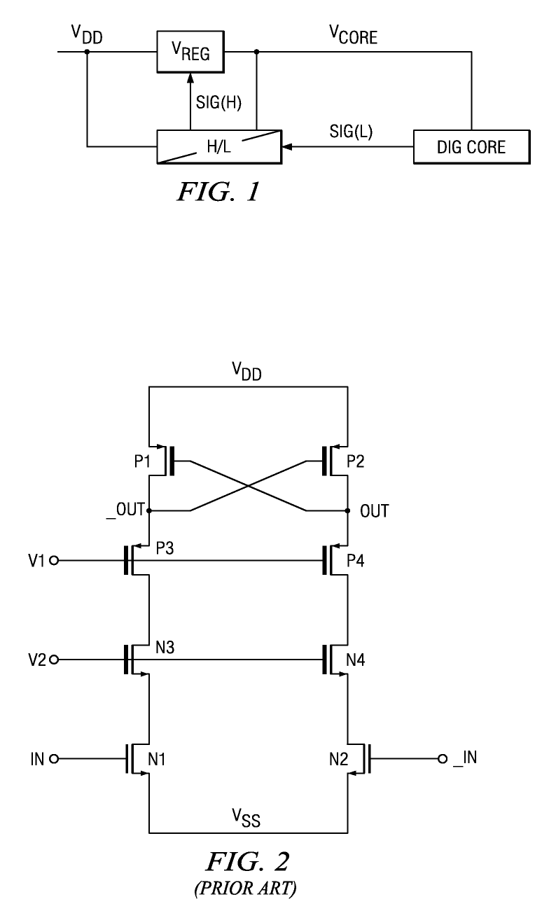

FIG. 1 shows a general block diagram of a circuit having two supply voltage domains. V_{DD} is the high positive supply voltage. The high positive supply voltage is converted into a low positive supply voltage V_{CORE} with a voltage regulator V_{REG}. The low supply voltage V_{CORE} is used to supply a digital core (DIG CORE), which might be a digital logic, a processor, microcontroller or the like. The signal level Sig(L) relates to digital signal levels in the low supply voltage domain having V_{CORE} as positive supply voltage. Sig(H) relates to digital signals having levels as required by the high voltage domain having V_{DD} as positive voltage. Since, for example, the voltage regulator V_{REG} requires signals in the high voltage domain a level converter H/L is provided for converting the signals Sig(L) from the low voltage domain V_{CORE} into signals Sig(H) of the high voltage domain V_{DD}.

FIG. 2 shows a simplified circuit diagram of a supply voltage level converter according to the prior art. As illustrated in FIG. 2 a transistor having a broad gate drawn as black bar indicates a device which is designed in a technology capable to withstand the higher supply voltage levels of the high voltage domain V_{DD}. Differential input voltages IN and _IN are from the low voltage domain V_{CORE}. The output signals OUT and _OUT are supplied to the high voltage domain V_{DD}. The differential architecture comprises transistor pairs P1/P2, and P3/P4 which are designed to be used in the high voltage domain V_{DD}. The transistors N3 and N4 are also high voltage compliant. Only N1 and N2 are implemented in a low voltage technology, so that they can only withstand voltage levels up to about V_{CORE}. Transistors N3 and N4 are biased by a specific gate voltage V_{CORE} or V2 to provide sufficient voltage drop across N3 and N4 to reduce the drain-source voltage across N1 and N2 to prevent N1 and N2 from being damaged. Transistors P3 and P4 are biased by bias voltage V1 in order to also decrease the voltage drop across the low voltage devices N1 and N2. The bias voltages V1 and V2 must be provided by additional circuitry. This increases chip area and power consumption of the prior art supply voltage level converter. The voltage swing of the output signals OUT and _OUT is reduced because the biased cascode devices P3, P4, N3 and N4 have considerable voltage drop. Thus the output signals will always remain substantially higher than V_{SS}. The six high voltage transistors N3, N4, P1, P2, P3 and P4 consume a substantial amount of chip area. This could be avoided if low supply voltage transistors can be used.

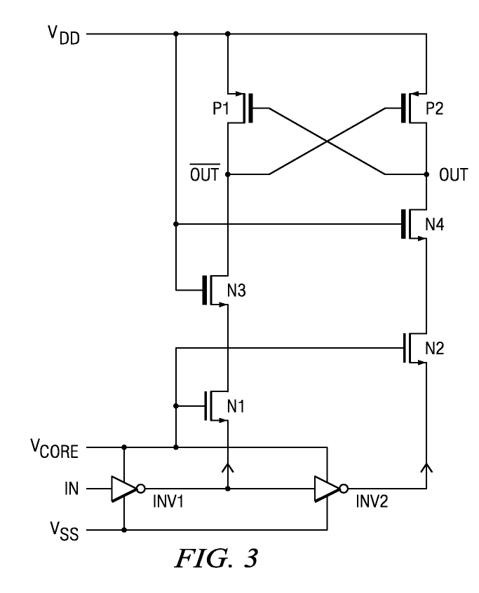

FIG. 3 shows a voltage level converter circuit according to the invention. As in FIG. 2, the black bar at the gate of a transistor indicates a high supply voltage device, i.e. a device designed in a technology suitable to withstand higher supply voltage levels. A chain of inverters is connected between a ground rail V_{SS} and a low positive supply voltage rail V_{CORE}. In this example these inverters are represented buy a first inverter INV1 and a second inverter INV2. Both inverters INV1 and INV2 are biased at a low voltage supply level. Input terminal IN receives the input signal to be converted from the low supply voltage level to a high supply voltage level at the input of first inverter INV1. The output of first inverter INV1 is connected to the input of second inverter INV2, and also to the source terminal of NMOS transistor N1. The output of second inverter INV2 is connected to the source terminal of NMOS transistor N2. The transistors N1 and N2 are cascode transistors and are low voltage compliant devices connected in a common gate configuration so that the gate terminals of both the transistors N1 and N2 are connected to the low supply voltage rail V_{CORE}. Low voltage compliant means these transistors have not only a restricted capability to withstand high drain source voltages. Transistors N1 and N2 are also designed to receive low gate voltages and therefore have low threshold voltages. The drain terminals of transistors N1 and N2 are connected to respective source terminals of two NMOS cascode transistors N3 and N4. The gates of transistors N3 and N4 are also coupled to each other in a common gate configuration to high positive supply voltage rail V_{DD}. Transistors N3 and N4 are high voltage compliant devices, which means that they are designed to operate with their gate terminals connected to the high supply voltage provided at the high positive supply voltage rail V_{DD}. The drain terminals of NMOS cascode transistors N3 and N4 are connected to respective drain terminals of high voltage compliant PMOS transistors P1 and P2. The source terminals of transistors P1 and P2 are both connected to the high supply voltage rail V_{DD}. Transistors P1 and P2 are cross coupled. The gate terminal of transistor P1 is connected to the drain terminals of transistors P2 and N4 and the gate terminal of transistor P2 is connected to the drain terminals of transistors P1 and N3. The node interconnecting the gate of the transistor P1 with the drains of the transistors P2 and N4 forms a first output node OUT providing an output signal according to the high voltage at the high supply voltage rail V_{DD}. The node interconnecting the gate of the transistor P2 with the drains of the transistors P1 and N3 forms a second output node _OUT providing a complementary output signal also according to the high voltage at the high supply voltage rail V_{DD}.

Inverters INV1 and INV2 are both supplied by the low supply voltage rail V_{CORE}. A low voltage input signal received at the input IN is output by the first and second inverters INV1 and INV2 to feed low voltage compliant cascode transistors N1 and N2. Transistors N1 and N2 feed respective high supply voltage compliant cascode transistors N3 and N4. Transistors N3 and N4 further feed cross coupled high supply voltage compliant transistors P1 and P2. The transistors N3 and N4 have gate voltages equal to the high voltage at the high supply voltage rail V_{DD} so that complementary output signals are then generated at the output nodes OUT and _OUT based on the voltage at the high supply voltage rail V_{DD}. The gates of transistors N3 and N4 are biased by the high supply voltage rail V_{DD} and because they are high voltage compliant devices, no separate biasing circuits are required.

Accordingly, the supply voltage level converter according to the prior does not need any additional biasing voltages. Bias circuitry is therefore not required. This saves chip area and power. Further, since transistors N1 and N2 in FIG. 3 are in common gate configuration, V_{SS} can be transferred to the drains of N1 and N2, which improves the switching speed of the whole circuit. This is due to smaller input capacitance of the present invention compared to the configuration shown in FIG. 2. In a common source configuration the gate-source and the gate-bulk capacitance have to be discharged and charged, i.e. the combined capacitance constitutes the load for signals IN and IN. In a common gate configuration according to the present invention, only the gate-source capacitance is relevant.

Although the present invention has been described with reference to a specific embodiment, it is not limited to this embodiment and no doubt further alternatives will occur to the skilled person that lie within the scope of the invention as claimed.

What is claimed is:

1. An electronic device with a supply voltage level converter for converting a signal from a first low supply voltage level (V_{CORE}) to a second high supply voltage level (V_{DD}), the supply voltage level converter comprising:
a first pair of cross coupled MOS transistors (P1, P2) compliant with said second supply voltage level (V_{DD}), each having a source coupled to said second supply voltage level (V_{DD}) and each having a drain being respective output nodes (OUT, _OUT) providing complementary output signals according to said second supply voltage level (V_{DD});
a second pair of MOS transistors (N3, N4) compliant with said second supply voltage level (V_{DD}), each having a gate receiving a first constant voltage level, each having a drain coupled to a drain of a corresponding one of said transistors in said first pair of cross coupled transistors (P1, P2);
a third pair of MOS transistors (N1, N2) compliant with said first voltage level (V_{CORE}), each having a gate receiving a second constant voltage level and each having a drain coupled to a source of a corresponding one of said transistor in said second pair of MOS transistors (N3, N4);
a first inverter (INV1) supplied by said first supply voltage level (V_{CORE}), having an input receiving an input signal (IN) and an output connected to a source of a first transistor (N1) of said third pair of MOS transistors (N1, N2); and
a second inverter (INV2) by said first supply voltage level (V_{CORE}), having an input connected to said output of said first inverter and an output connected to a source of a second transistor (N2) of said third pair of MOS transistors (N1, N2).

2. The electronic device according to claim 1, wherein:
said first constant voltage level is the second supply voltage (V_{DD}).

3. The electronic device according to claim 1, wherein:
said second constant voltage level is the first supply voltage (V_{CORE}).
